(19) United States
(12) Patent Application Publication
(10) Pub. No.: US 2026/0309241 A1
(43) Pub. Date: Oct. 8, 2026

(54) MULTI-WAY VALVE AND THERMAL MANAGEMENT SYSTEM INCLUDING THE SAME

(71) Applicant: Hanon Systems, Daejeon (KR)

(72) Inventors: Shin-Won YUN, Daejeon (KR); Jeong Wan HAN, Daejeon (KR)

(73) Assignee: Hanon Systems, Daejeon (KR)

(21) Appl. No.: 19/434,902

(22) Filed: Dec. 29, 2025

(30) Foreign Application Priority Data
Jan. 3, 2025 (KR) 10-2025-0000746

(51) Int. Cl. F16K 11/085; H05K 7/20; H01M 10/613

(52) U.S. Cl. CPC F16K 11/0853; H05K 7/20281; H01M 10/613

(57) ABSTRACT

The present disclosure relates to a multi-way valve and a thermal management system including the same, and the multi-way valve in the embodiment may include a body, a plurality of ports formed in an outer peripheral surface of the body, a plurality of flow paths configured to selectively connect the plurality of ports, a separation wall configured to divide the inside of the body into a plurality of chambers, and a communication flow path formed between at least any one of the plurality of chambers and another chamber and configured to allow the two chambers to fluidly communicate with each other.

### CROSS-REFERENCE TO RELATED APPLICATION

The present application claims priority to Korean Patent Application No. 10-2025-0000746, filed on Jan. 03, 2025, the entire contents of which are incorporated herein for all purposes by this reference.

### BACKGROUND OF THE DISCLOSURE

### Field of the Disclosure

The present disclosure relates to a multi-way valve configured to control a flow direction of a fluid, and a thermal management system including the same.

### Description of the Related Art

An air conditioning system for a vehicle circulates a coolant to cool or heat an interior of the vehicle or manage temperatures of a battery, a PE module, and the like. A multi-way valve may control a flow direction of the coolant and guide the coolant to various paths to implement various modes such as cooling, heating, outside-air circulation, battery cooling, and PE module cooling modes.

A change in pressure in the valve may occur when the mode of the multi-way valve is changed, and as a result, a section, in which pressure is decreased for a moment, may occur. The decrease in pressure may cause air in a coolant line to be introduced into the valve.

In case that the air is introduced into the multi-way valve, the air is mixed with the coolant, which may hinder a flow of the coolant and degrade heat transfer efficiency of the air conditioning system. In addition, the air moves along the coolant line, which may cause noise of a water pump or the like. Further, the air is trapped in the valve, which may obstruct the operation of the valve or cause damage to the valve.

### Document of Related Art

[Patent Document] Korean Patent Application Laid-Open No. 10-2024-0018104 (published on Feb. 13, 2024)

### SUMMARY OF THE DISCLOSURE

The present disclosure is proposed to solve these problems and aims to provide a multi-way valve capable of reducing cavitation by receiving pressure compensation from a separate chamber connected to a communication flow path even though an instantaneous pressure drop occurs in a specific chamber in the valve.

The present disclosure also aims to provide a multi-way valve in which a communication flow path is configured without adding a separate component, thereby reducing manufacturing costs.

The present disclosure also aims to provide a thermal management system in which the introduction of air into a water pump connected to a multi-way valve is reduced, thereby reducing operational noise and improving efficiency in circulating a coolant.

Technical problems of the present disclosure are not limited to the aforementioned technical problems, and other technical problems, which are not mentioned above, may be clearly understood by those skilled in the art from the following descriptions.

The present disclosure relates to a multi-way valve for controlling a flow direction of a fluid, and a thermal management system including the same, and the multi-way valve in the embodiment may include a body, a plurality of ports formed in an outer peripheral surface of the body, a plurality of flow paths configured to selectively connect the plurality of ports, a separation wall configured to divide the inside of the body into a plurality of chambers, and a communication flow path formed between at least any one of the plurality of chambers and another chamber and configured to allow the two chambers to fluidly communicate with each other.

When the chamber connected to one side of the communication flow path is referred to as a first chamber and the chamber connected to the other side of the communication flow path is referred to as a second chamber, the second chamber may receive pressure compensation through the first chamber connected to the communication flow path.

At least one of the ports, which are formed in a region of the first chamber among the plurality of ports, may be connected to a reservoir tank.

At least one of the ports, which are formed in a region of the second chamber among the plurality of ports, may be connected to a water pump.

The multi-way valve may include: a first separation wall configured to define the first chamber; and a second separation wall configured to define the second chamber, in which slots are respectively formed at one side of the first separation wall and one side of the second separation wall and penetrate the first separation wall and the second separation wall, and the communication flow path extends from the slot of the first separation wall to the slot of the second separation wall.

The communication flow path may be formed straight from the slot of the first separation wall to the slot of the second separation wall.

The communication flow path may be bent one or more times from the slot of the first separation wall to the slot of the second separation wall.

A thermal management system according to an embodiment of the present disclosure may include: a first cooling line connected to a battery and configured to allow a coolant to flow therethrough; a second cooling line connected to a PE module and configured to allow the coolant to flow therethrough; a third cooling line in which a reservoir tank configured to accommodate the coolant and a radiator configured to cool the coolant are disposed; and a multi-way valve configured to selectively connect the first to third cooling lines by selectively connecting a plurality of ports, in which the multi-way valve includes: a body; the plurality of ports formed in an outer peripheral surface of the body; a plurality of flow paths configured to selectively connect the plurality of ports; a separation wall configured to divide the inside of the body into a plurality of chambers; and a communication flow path formed between at least any one of the plurality of chambers and another chamber and configured to allow the two chambers to fluidly communicate with each other, and in which a first chamber connected to one side of the communication flow path is configured to be connected to the third cooling line, and a second chamber connected to the other side of the communication flow path is configured to be connected to the first cooling line or the second cooling line.

The second chamber may receive pressure compensation through the first chamber connected to the communication flow path.

The thermal management system may further include: a first pump disposed in the first cooling line and configured to circulate the coolant to the battery.

The other side of the communication flow path may be connected to a front end of the port that communicates with the first pump among the ports formed in a region of the second chamber.

The thermal management system may further include: a second pump disposed in the second cooling line and configured to circulate the coolant to the PE module.

The other side of the communication flow path may be connected to a front end of the port that communicates with the second pump among the ports formed in a region of the second chamber.

A first separation wall, which defines the chamber connected to the first cooling line or the second cooling line, and a second separation wall, which defines the chamber connected to the third cooling line, may be provided in the body, slots may be respectively formed at one side of the first separation wall and one side of the second separation wall and penetrate the first separation wall and the second separation wall, and the communication flow path may extend from the slot of the first separation wall to the slot of the second separation wall.

### BRIEF DESCRIPTION OF THE DRAWINGS

FIG. 1 is an overall perspective view illustrating a multi-way valve according to an embodiment of the present disclosure.

FIGS. 2 and 3 are top plan views illustrating the inside of the multi-way valve.

FIG. 4 is a perspective view illustrating the inside of the multi-way valve.

FIG. 5 is a schematic view illustrating a thermal management system according to the embodiment of the present disclosure.

FIG. 6 is a schematic view illustrating a thermal management system according to another embodiment of the present disclosure.

### DETAILED DESCRIPTION OF THE DISCLOSURE

Hereinafter, the present disclosure will be described in detail with reference to the accompanying drawings. However, this is provided for illustrative purposes only, and the present disclosure is not limited to the exemplarily described specific embodiment.

The present disclosure relates to a multi-way valve configured to determine a flow direction of a fluid, and a thermal management system including the same. The present disclosure may be applied to vehicles including hybrid electric vehicles, fuel vehicles, and pure electric vehicles and applied to an air conditioning system and a configuration for cooling components of a vehicle.

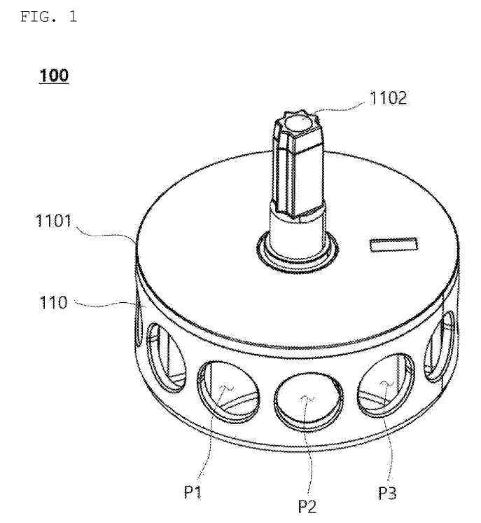

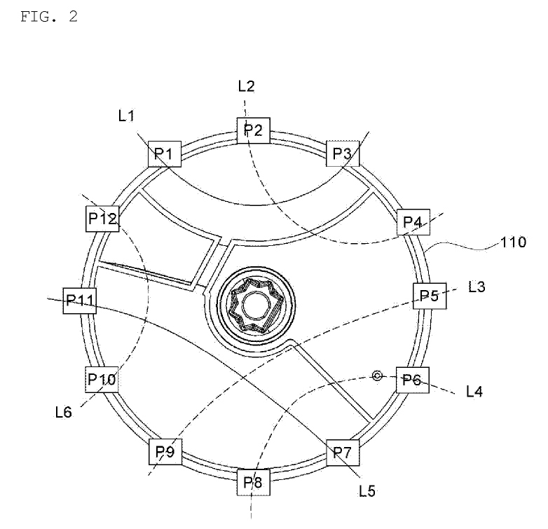

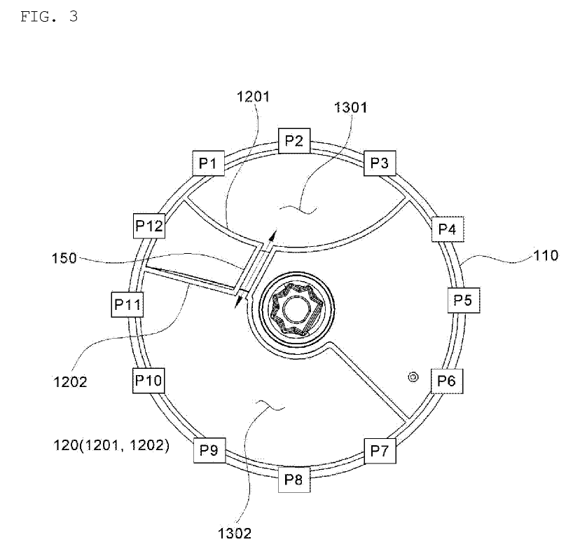

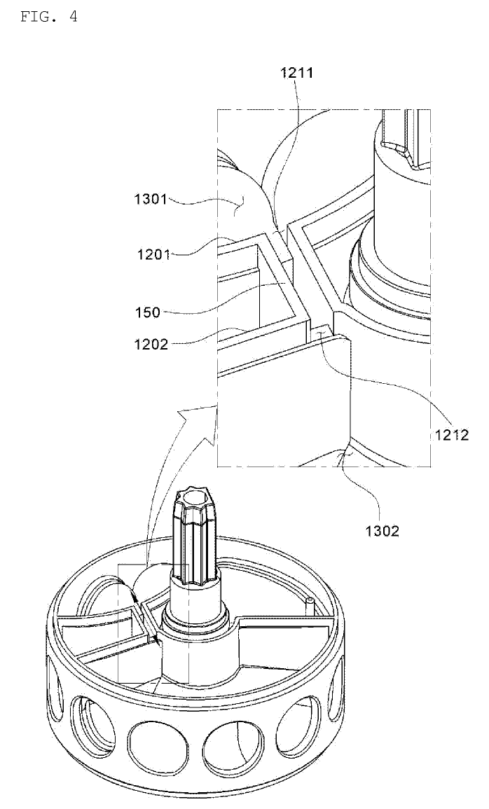

Hereinafter, a multi-way valve 100 according to an example of the present disclosure will be described with reference to FIGS. 1-4. FIG. 1 is an overall perspective view illustrating a multi-way valve according to an embodiment of the present disclosure, FIGS. 2 and 3 are top plan views illustrating the inside of the multi-way valve, and FIG. 4 is a perspective view illustrating the inside of the multi-way valve.

The multi-way valve 100 according to the embodiment of the present disclosure may be used to control a flow direction of a coolant. The multi-way valve 100 may include a body 110, a plurality of ports P1, P2, …, and Pn (n is a natural number of 2 or more) formed in an outer peripheral surface of the body 110, a plurality of flow paths L1, L2, …, and Lm (m is a natural number of 2 or more) configured to selectively connect the plurality of ports, separation walls 120 configured to divide the inside of the body 110 into a plurality of chambers, and a communication flow path 150 formed between at least any one of the plurality of chambers and another chamber and configured to allow the two chambers to fluidly communicate with each other.

In the embodiment, when a chamber connected to one side of the communication flow path 150 is referred to as a first chamber 1301 and a chamber connected to the other side of the communication flow path 150 is referred to as a second chamber 1302, the second chamber 1302 may receive pressure compensation through the first chamber 1301 connected to the communication flow path 150. The communication flow path 150 may be formed to traverse a partial space of the inside of the body 110 that excludes a region in which the first chamber 1301 and the second chamber 1302 are defined.

The multi-way valve 100 may implement various types of flow modes by selectively opening and closing the plurality of ports while rotating about a rotary shaft 1102. In case that the flow mode of the valve is changed or in case that a duty of a water pump connected to the valve is changed, a flow rate of the coolant flowing in a specific chamber may be changed, and an instantaneous pressure drop may occur. According to the present disclosure, even though an instantaneous pressure drop occurs in a specific chamber, pressure compensation may be received from the communication flow path and the chambers connected through the communication flow path. Therefore, it is possible to minimize the amount of air to be introduced into the multi-way valve and reduce cavitation.

Hereinafter, the description will be made with reference to FIGS. 2 and 3. FIGS. 2 and 3 illustrate that twelve ports P1, P2, …, and P12 are formed along a circumferential surface of the body 110, and six flow paths L1, L2, …, and L6 are formed to allow the flow paths L1, L2, …, and L6 to communicate with one another. However, this configuration is provided for illustrative purposes only, and the present disclosure is not limited thereto as long as the flow direction of the coolant may be determined by means of the plurality of ports and the plurality of flow paths that selectively connect the plurality of ports.

The plurality of ports may be radially formed in the body 110 along the circumferential surface of the body 110. When the body 110 rotates by a predetermined angle about the rotary shaft, whether the plurality of ports radially formed are opened or closed may be determined, and the flow direction of the coolant may be controlled.

The plurality of flow paths may define a multilayer structure. In FIG. 2, the flow paths formed in an upper layer are indicated by solid lines, and the flow paths formed in a lower layer are indicated by dotted lines. However, this configuration is provided for illustrative purposes only, and the structures of the flow paths for the respective layers and the ports configured to communicate with one another through the flow paths are not limited thereto.

In the embodiment, an internal space of the body 110 may be divided into the plurality of chambers by the plurality of separation walls. FIG. 3 exemplarily illustrates that the first chamber 1301 is defined by a first separation wall 1201, and the second chamber 1302 is defined by a second separation wall 1202.

The plurality of ports may be formed to communicate with any one of the plurality of chambers. FIG. 3 exemplarily illustrates that the ports P1, P2, and P3 are formed in the first chamber 1301, and the ports P7, P8, P9, P10, and P11 are formed in the second chamber 1302.

In the embodiment, at least one of the ports, which are formed in a region of the first chamber 1301 among the plurality of ports, may be connected to a reservoir tank. The reservoir tank may have a predetermined volume so that the coolant may be stored in the reservoir tank. Even though an instantaneous pressure drop occurs in the second chamber 1302, the second chamber 1302 may fluidly communicate with the first chamber 1301 connected to the reservoir tank and receive pressure compensation. That is, the first chamber 1301 connected to the reservoir tank may provide a space capable of receiving a change in pressure in the flow path and alleviate an instantaneous change in pressure in the second chamber 1302 through the communication flow path 150 connected to the first chamber 1301.

In the embodiment, at least one of the ports, which are formed in a region of the second chamber 1302 among the plurality of ports, may be connected to the water pump. In case that a duty ratio of the water pump increases, an instantaneous pressure drop may occur in the second chamber 1302 connected to a front end of the water pump, but it is possible to receive pressure compensation through the first chamber 1301 and the communication flow path 150.

The chamber connected to the reservoir tank may sufficiently receive a pressure change, and a pressure drop is highly likely to occur in the chamber connected to the water pump. Therefore, the pressure compensation of the chamber, in which the port connected to the water pump is disposed, may be implemented from the chamber in which the port connected to the reservoir tank among the plurality of chambers is disposed. According to the present disclosure, the communication flow path 150 may be provided to fluidly connect the first chamber 1301, which is formed with the port connected to the reservoir tank, and the second chamber 1302 formed with the port connected to the water pump, thereby efficiently compensating for the pressure drop in the second chamber 1302.

Hereinafter, the communication flow path 150 will be specifically described with reference to FIG. 4.

In the embodiment, the inside of the body 110 may be divided into the first chamber 1301 defined by the first separation wall 1201, and the second chamber 1302 defined by the second separation wall 1202.

Slots 1211 and 1212 may be respectively formed at one side of the first separation wall 1201 and one side of the second separation wall 1202 and penetrate the first separation wall 1201 and the second separation wall 1202, and the communication flow path 150 may extend from the slot 1211 of the first separation wall 1201 to the slot 1212 of the second separation wall 1202.

In the embodiment, the communication flow path 150 may be formed straight from the slot 1211 of the first separation wall to the slot 1212 of the second separation wall.

In another embodiment, the communication flow path 150 may be bent one or more times from the slot 1211 of the first separation wall to the slot 1212 of the second separation wall.

The straight communication flow path may allow the fluid to smoothly flow, and the bent communication flow path may adjust the flow rate by applying resistance to the flow of the fluid. According to the present disclosure, the shape of the communication flow path 150 may be selectively applied in accordance with a required flow rate.

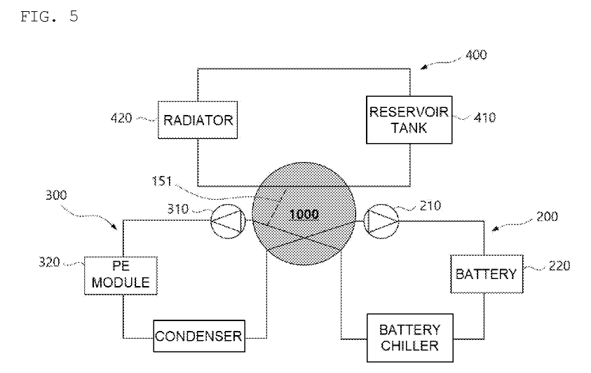

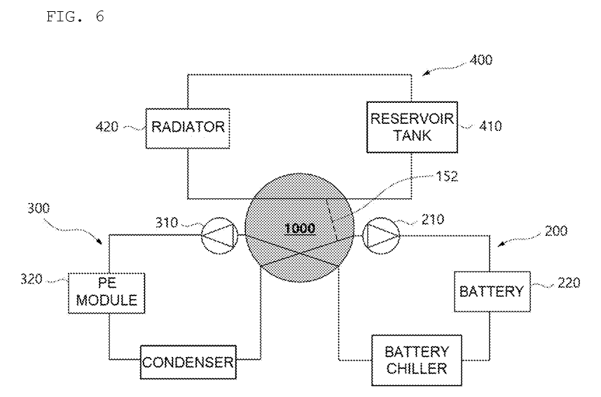

The multi-way valve 100 according to the present disclosure has been described above. Hereinafter, a thermal management system 2000 according to the present disclosure will be described with reference to FIGS. 5 and 6. FIG. 5 is a schematic view illustrating a thermal management system according to the embodiment of the present disclosure, and FIG. 6 is a schematic view illustrating a thermal management system according to another embodiment of the present disclosure.

The thermal management system 2000 may include a first cooling line 200 connected to a battery 220 and configured to allow the coolant to flow therethrough, a second cooling line 300 connected to a PE module 320 and configured to allow the coolant to flow therethrough, a third cooling line 400 in which a reservoir tank 410 configured to accommodate the coolant and a radiator 420 configured to cool the coolant are disposed, and the multi-way valve 1000 configured to selectively connect the first to third cooling lines by selectively connecting the plurality of ports.

The first cooling line 200 cools the battery 220 by circulating the coolant. A first pump 210 and the battery 220 may be disposed in the first cooling line 200, and a battery chiller may be further disposed in the first cooling line 200. The first pump 210 allows the coolant to circulate along the first cooling line 200 and supplies the coolant to the battery 220.

The second cooling line 300 cools the PE module 320 by circulating the coolant. A second pump 310, the PE module 320, and a condenser configured to allow heat exchange fluids to exchange heat with each other may be disposed in the second cooling line 300. For example, the condenser may condense a refrigerant by means of heat exchange between the coolant and the refrigerant. The second pump allows the coolant to circulate along the second cooling line 300. In one example, the PE module 320 may include a motor, an inverter, a speed reducer, or the like.

The reservoir tank 410 configured to store the coolant and the radiator 420 configured to circulate the coolant may be provided in the third cooling line 400. In the thermal management system 1000 according to the embodiment, the coolant is cooled by the radiator 420, and the coolant circulates along the cooling lines in which the battery 220 and the PE module 320 are disposed, thereby cooling the battery and the PE module.

The thermal management system 2000 may include the multi-way valve configured to control the flow direction of the coolant. In this case, the multi-way valve may correspond to one of the plurality of embodiments of the multi-way valve 100.

The multi-way valve 1000 may be provided to selectively connect the first to third cooling lines. For example, i) the first to third cooling lines may constitute a separate closed circuit without being connected to one another, ii) the first cooling line 200 and the second cooling line 300 are connected, iii) the third cooling line 400 is connected to the first cooling line 200, iv) the third cooling line 400 is connected to the second cooling line 300, or v) the third cooling line 400 may be connected to both the first cooling line 200 and the second cooling line 300.

In the multi-way valve 100, the first chamber connected to one side of the communication flow path 150 may be configured to be connected to the third cooling line 400 in which the reservoir tank 410 is disposed, and the second chamber connected to the other side of the communication flow path 150 may be configured to be connected to the first cooling line 200 or the second cooling line 300.

The second chamber may receive pressure compensation through the first chamber connected to the reservoir tank 410, such that cavitation does not occur in the second chamber. Therefore, there is an advantage in that the operational efficiency of the water pumps connected to the second chamber is improved, and noise is reduced.

In the embodiment according to FIG. 5, the second pump 310 configured to circulate the coolant to the PE module 320 may be disposed in the second cooling line 300. The second pump 310 may communicate with one of the plurality of ports formed in the multi-way valve 100 and provide power for allowing the coolant introduced into the multi-way valve 100 to circulate along the second cooling line 300.

In this case, one side of a communication flow path 151 may be connected to the first chamber of the multi-way valve 100, and the other side of the communication flow path 151 may be connected to a front end of the port that communicates with the second pump 310 among the ports formed in the region of the second chamber.

In another embodiment according to FIG. 6, the first pump 210 configured to circulate the coolant to the battery 220 may be disposed in the first cooling line 200. The first pump 210 may communicate with one of the plurality of ports formed in the multi-way valve 100 and provide power for allowing the coolant introduced into the multi-way valve 100 to circulate along the first cooling line 200.

In this case, one side of a communication flow path 152 may be connected to the first chamber of the multi-way valve 100, and the other side of the communication flow path 152 may be connected to a front end of the port that communicates with the first pump 210 among the ports formed in the region of the second chamber.

Therefore, even though the flow rate of the coolant in the multi-way valve is changed, such as in case that a duty of the pump is changed, it is possible to prevent an instantaneous pressure drop from occurring in the valve and to reduce cavitation.

According to the embodiment of the present disclosure, it is possible to reduce cavitation in the multi-way valve by receiving the pressure compensation from a separate chamber connected to the communication flow path even though an instantaneous pressure drop occurs in a specific chamber in the valve.

In addition, the communication flow path is configured in the multi-way valve without adding a separate component, thereby reducing costs for manufacturing the multi-way valve.

In addition, the introduction of air into the water pump connected to the multi-way valve may be reduced, thereby reducing operational noise and improving efficiency in circulating the coolant in the thermal management system.

The effects of the present disclosure are not limited to the above-mentioned effects, and other effects, which are not mentioned above, may be clearly understood by those skilled in the art from the present specification and the accompanying drawings.

While the embodiments of the present disclosure have been described with reference to the accompanying drawings, those skilled in the art will understand that the present disclosure may be carried out in any other specific form without changing the technical spirit or an essential feature thereof. Therefore, it should be understood that the above-described embodiments are illustrative in all aspects and do not limit the present disclosure.

### DESCRIPTION OF REFERENCE NUMERALS

100: Multi-way valve

110: Body

1101: Cover

P1, P2, …, Pn: Port

L1, L2, …, Lm: Flow path

120: Separation wall

1201: First separation wall

1202: Second separation wall

1211: First slot

1212: Second slot

1301: First chamber

1302: Second chamber

150 (151, 152): Communication flow path

200: First cooling line

210: First pump

220: Battery

300: Second cooling line

310: Second pump

320: PE module

400: Third cooling line

410: Reservoir tank

420: Radiator

What is claimed is:

1. A multi-way valve for controlling a flow direction of a fluid, the multi-way valve comprising:
a body;
a plurality of ports formed in an outer peripheral surface of the body;
a plurality of flow paths configured to selectively connect the plurality of ports;
a separation wall configured to divide the inside of the body into a plurality of chambers; and
a communication flow path formed between at least any one of the plurality of chambers and another chamber and configured to allow the two chambers to fluidly communicate with each other.

2. The multi-way valve of claim 1, wherein when the chamber connected to one side of the communication flow path is referred to as a first chamber and the chamber connected to the other side of the communication flow path is referred to as a second chamber, the second chamber receives pressure compensation through the first chamber connected to the communication flow path.

3. The multi-way valve of claim 2, wherein at least one of the ports, which are formed in a region of the first chamber among the plurality of ports, is connected to a reservoir tank.

4. The multi-way valve of claim 3, wherein at least one of the ports, which are formed in a region of the second chamber among the plurality of ports, is connected to a water pump.

5. The multi-way valve of claim 2, comprising:
a first separation wall configured to define the first chamber; and
a second separation wall configured to define the second chamber,
wherein slots are respectively formed at one side of the first separation wall and one side of the second separation wall and penetrate the first separation wall and the second separation wall, and the communication flow path extends from the slot of the first separation wall to the slot of the second separation wall.

6. The multi-way valve of claim 5, wherein the communication flow path is formed straight from the slot of the first separation wall to the slot of the second separation wall.

7. The multi-way valve of claim 5, wherein the communication flow path is bent one or more times from the slot of the first separation wall to the slot of the second separation wall.

8. The multi-way valve of claim 2, wherein the plurality of ports are radially formed in the body along a circumferential surface of the body, and the body controls a flow direction of a coolant while rotating about a rotary shaft.

9. A thermal management system comprising:
a first cooling line connected to a battery and configured to allow a coolant to flow therethrough;
a second cooling line connected to a PE module and configured to allow the coolant to flow therethrough;
a third cooling line in which a reservoir tank configured to accommodate the coolant and a radiator configured to cool the coolant are disposed; and
a multi-way valve configured to selectively connect the first to third cooling lines by selectively connecting a plurality of ports,
wherein the multi-way valve comprises:
a body;
the plurality of ports formed in an outer peripheral surface of the body;
a plurality of flow paths configured to selectively connect the plurality of ports;
a separation wall configured to divide the inside of the body into a plurality of chambers; and
a communication flow path formed between at least any one of the plurality of chambers and another chamber and configured to allow the two chambers to fluidly communicate with each other, and
wherein a first chamber connected to one side of the communication flow path is configured to be connected to the third cooling line, and a second chamber connected to the other side of the communication flow path is configured to be connected to the first cooling line or the second cooling line.

10. The thermal management system of claim 9, wherein the second chamber receives pressure compensation through the first chamber connected to the communication flow path.

11. The thermal management system of claim 10, further comprising:
a first pump disposed in the first cooling line and configured to circulate the coolant to the battery.

12. The thermal management system of claim 11, wherein the other side of the communication flow path is connected to a front end of the port that communicates with the first pump among the ports formed in a region of the second chamber.

13. The thermal management system of claim 10, further comprising:
a second pump disposed in the second cooling line and configured to circulate the coolant to the PE module.

14. The thermal management system of claim 13, wherein the other side of the communication flow path is connected to a front end of the port that communicates with the second pump among the ports formed in a region of the second chamber.

15. The thermal management system of claim 9, wherein a first separation wall, which defines the chamber connected to the first cooling line or the second cooling line, and a second separation wall, which defines the chamber connected to the third cooling line, are provided in the body,
wherein slots are respectively formed at one side of the first separation wall and one side of the second separation wall and penetrate the first separation wall and the second separation wall, and
wherein the communication flow path extends from the slot of the first separation wall to the slot of the second separation wall.
